(19) United States
(12) Patent Application Publication
(10) Pub. No.: US 2008/0158810 A1
(43) Pub. Date: Jul. 3, 2008

(54) HARD DISK DRIVE DRAWER

(75) Inventors: Kuo-Kuang LIU, Caotun Township (TW); Te-Sheng Liu, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., Ltd., Tsao Tuen (TW)

(21) Appl. No.: 11/934,985

(22) Filed: Nov. 5, 2007

(30) Foreign Application Priority Data
Dec. 29, 2006 (TW) 095223255

(51) Int. Cl. H05K 13/04

(52) U.S. Cl. 361/685

(57) ABSTRACT

A hard disk drive drawer includes a fixed casing mountable inside a computer housing, and a drawable carrier, which is elastically deformable for holding a hard disk drive therein and detachably and slidably received in the fixed casing. The fixed casing has a retaining portion. A handle is pivotally connected with the drawable carrier and provided with a locating member, which is engageable with the retaining portion of the fixed casing when the drawable carrier is received in the fixed casing and the handle is turned relative to the drawable carrier to a vertical locking position.

### BACKGROUND OF THE INVENTION

1. Field of the Invention

The present invention relates generally to computer hard disk drives and more specifically, to a hard disk drive drawer including a fixed casing adapted to be fixed inside a computer housing and a drawable carrier, which is moveably receivable in the fixed casing, for holding the hard disk drive therein.

2. Description of the Related Art

As shown in FIG. 10, a conventional computer hard disk drive drawer comprises an outer frame member 70 and an inner frame member 80. The inner frame member 80 is adapted to hold a hard disk drive, and is moveably receivable in the outer frame member 70 for enabling insertion and withdrawal of the hard disk drive into/out of the outer frame member 70. By means of withdrawal and exchange of the inner frame member 80, the user can quickly remove and replace a hard disk drive.

According to the aforesaid design, the user must install the outer frame member 70 in the computer housing and fasten the hard disk drive in the inner frame member 80 by means of screws and screwdriver, thereby requiring much time in installation. Further, this structure does not provide a grounding arrangement to protect the hard disk drive against possible electro-static discharge (hereinafter referred to as “ESD”) damage. Therefore, the hard disk drive is not free from the risk of ESD damage.

### SUMMARY OF THE INVENTION

The present invention has been accomplished in view of the above-noted circumstance. It is therefore one objective of the present invention to provide a hard disk drive drawer, which is easy to install and operate, and convenient in use.

It is another objective of the present invention to provide a hard disk drive drawer, which can be well grounded for preventing the hard disk drive installed therein from ESD damage.

To achieve these objectives of the present invention, the hard disk drive drawer provided by the present invention comprises a fixed casing, a drawable carrier and a handle. The fixed casing, which has a retaining portion, is mountable inside a computer housing. The drawable carrier, which is detachably and slidably received in the fixed casing, is elastically deformable for holding a hard disk drive therein. The handle is pivotally connected with the drawable carrier and provided with a locating member. The locating member of the handle is engageable with the retaining portion of the fixed casing when the drawable carrier is received in the fixed casing and the handle is turned relative to the drawable carrier to a locking position so as to lock the drawable carrier to the fixed casing.

The hard disk drive drawer can further includes at least one spring strip mounted in the drawable carrier and closely attachable between the fixed casing that is grounded with the computer housing and the hard disk drive carried in the drawable carrier, such that the hard disk drive can be grounded so as to prevent itself from ESD damage.

In an exemplary embodiment of the present invention to be detailed described hereinafter, the fixed casing comprises two opposite lateral sidewalls on each of which a bearing portion is provided for supporting the drawable carrier inside the fixed casing. The bearing portions of the fixed casing are plates formed by stamping and bending on the opposite lateral sidewalls of the fixed casing and extending respectively and horizontally from the opposite lateral sidewalls of the fixed casing into a receiving space inside the fixed casing.

Further, the handle is substantially a U-shaped member having two arms, each of which has a pivot pivotally inserted into a pivot hole provided at each of two opposite lateral sidewalls of the drawable carrier.

Furthermore, the retaining portion of the fixed casing is a slot having a horizontal section and an upright end, and the locating member of the handle is a rod member having a substantially semicircle-shaped cross-section, which is slidably insertable into the horizontal section of the slot when the handle is kept horizontal relative to the drawable carrier and engageable with the upright end of the slot when the handle is turned relative to the drawable carrier to a vertical locking position.

The hard disk drive drawer provided by the present invention utilizes the elastically deformable characteristic of the drawable carrier for easy and quick installation of the hard disk drive, and the at least one spring strip acts as a bridge connecting the hard disk drive carried in the drawable carrier and the grounded fixed casing, thereby providing the hard disk drive a protection against ESD damage.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded view of a drawable carrier, two spring strips and a handle of a hard disk drive drawer according to an exemplary embodiment of the present invention;

FIG. 2 is a rear view of the handle shown in FIG. 1;

FIG. 3 is a perspective view illustrating that the drawable carrier, the spring strips and the handle are assembled together before installation of a hard disk drive in the drawable carrier;

FIG. 4 is a perspective assembly view illustrating that the drawable carrier, the spring strips and the handle are assembled together and the hard disk drive is installed inside the drawable carrier;

FIG. 5 is a partially exploded view of the hard disk drive drawer of the present invention, showing that the drawable carrier is going to be installed into the fixed casing;

FIG. 6 is a perspective view of the hard disk drive drawer of the present invention, showing that the drawable carrier is inserted into the fixed casing;

FIG. 7 is a sectional view in an enlarged scale of a part of FIG. 6, showing that the locating member is inserted into the horizontal section of the retaining portion of the fixed casing;

FIG. 8 is similar to FIG. 6, but showing that the handle is turned relative to the drawable carrier to a locking position and received in the fixed casing;

FIG. 9 is a sectional view in an enlarged scale of a part of FIG. 8, showing that the locating member is engaged with the upright end of the retaining portion of the fixed casing; and

FIG. 10 is a schematic drawing, showing a conventional hard disk drive drawer according to a prior art.

### DETAILED DESCRIPTION OF THE INVENTION

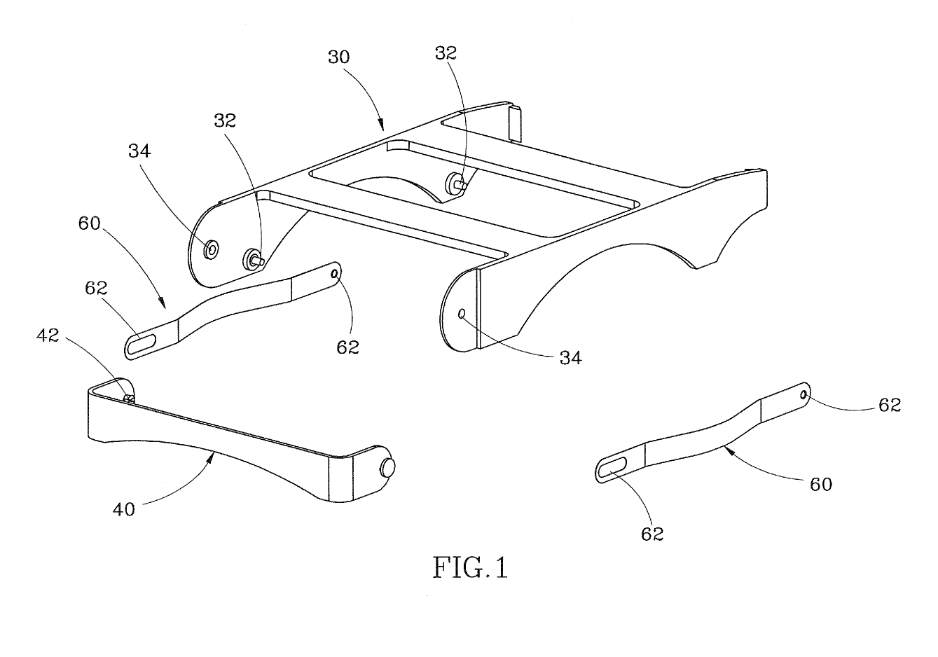

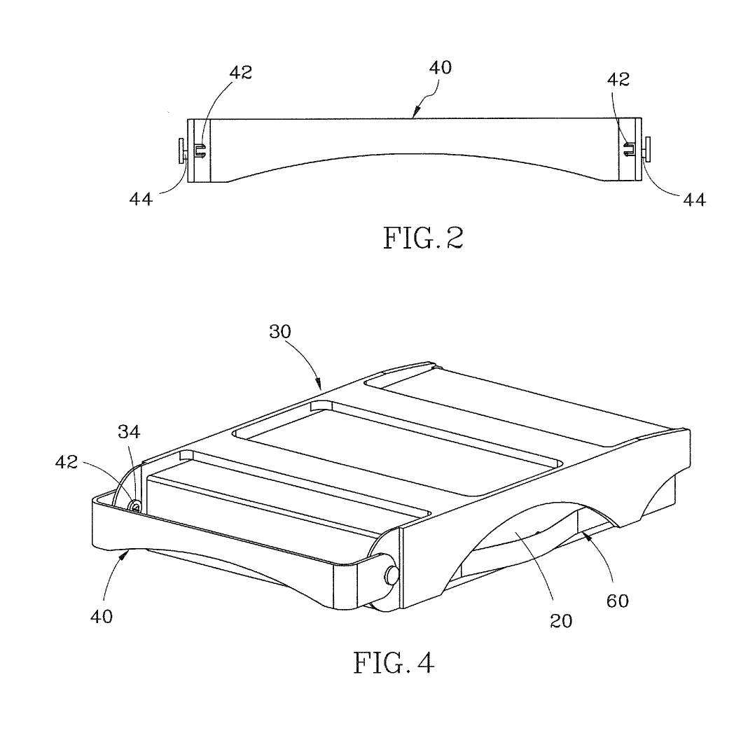

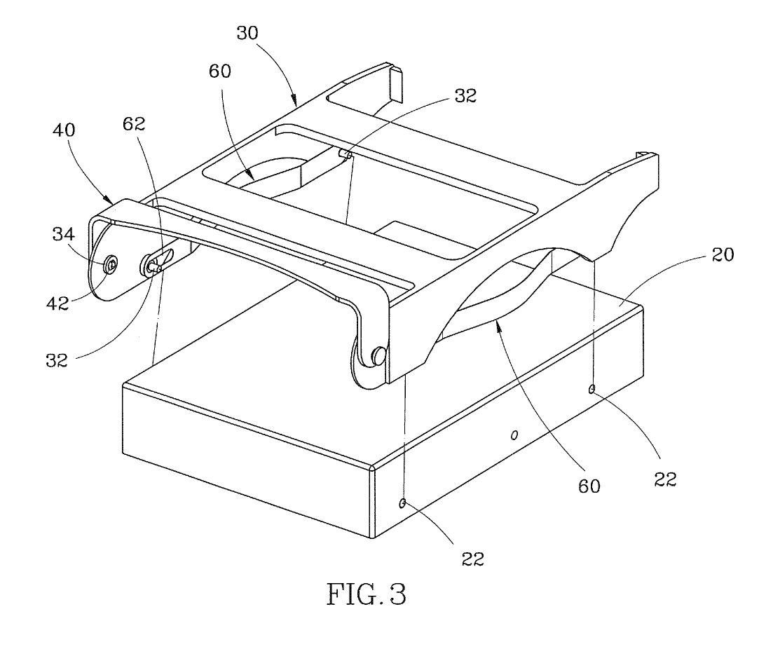

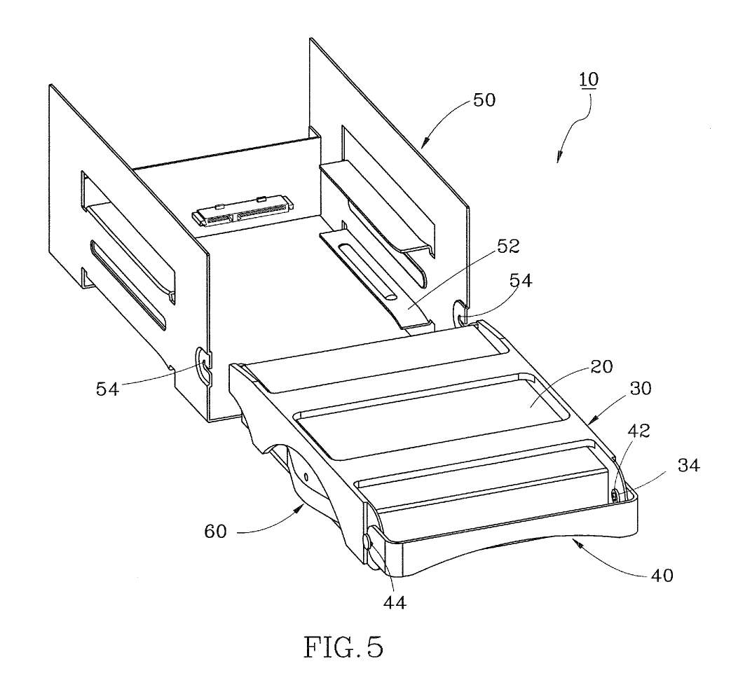

Referring to FIGS. 1-9, a hard disk drive drawer 10 in accordance with an exemplary embodiment of the present invention is adapted to be fixed inside a computer housing (not shown) for holding a hard disk drive 20 therein. As shown in FIG. 3, the hard disk drive 20 has a plurality of mounting holes 22 on its two opposite lateral sides. Since the hard disk drive 20 is a memory device of a conventional design, no further detailed description in this regard is necessary. The hard disk drive drawer 10 comprises a drawable carrier 30, a handle 40, a fixed casing 50 and two spring strips 60.

The drawable carrier 30 is an elastically deformable single-piece member, having two opposite lateral sidewalls, a plurality of mounting pins 32 outwardly protruding from inner surfaces of the two opposite lateral sidewalls, and two pivot holes 34 respectively provided at the two opposite lateral sidewalls. The mounting pins 32 are used to be respectively fitted into the mounting holes 22 of the hard disk drive 20 to secure the hard disk drive 20 to the drawable carrier 30.

The handle 40 is a U-shaped member having two arms, two pivots 42 and two locating members 44. The pivots 42 respectively outwardly extend from the inner surfaces of the two arms of the handle 40 and are respectively and pivotally insertable into the pivot holes 34 of the drawable carrier 30 for pivotally securing the handle 40 to the drawable carrier 30. The locating members 44 are rod members having a substantially semicircle-shaped cross section.

The fixed casing 50 is a metal frame, having an inside receiving space and a front open side in communication with the inside receiving space and the outside space, two opposite lateral sidewalls, two bearing portions 52 respectively provided at the inner surfaces of the lateral sidewalls, and two retaining portions 54 at the front portions of the lateral sidewalls. The bearing portions 52 are plates made by stamping and bending on the lateral sidewalls. The bearing portions 52 respectively and horizontally extend from the inner surfaces of the lateral sidewalls and are suspended in the receiving space of the fixed casing 50 for supporting the hard disk drive 20 and the drawable carrier 30. The retaining portions 54 are curved slots symmetrically formed at the front portions of the lateral sidewalls of the fixed casing 50 and each having a horizontal section and an upright end. The locating members 44 of the handle 40 can be respectively inserted into the horizontal sections of the retaining portions 54 when the handle 40 is kept horizontal relative to the drawable carrier 30. After complete insertion of the locating members 44 of the handle 40 into the horizontal sections of the retaining portions 54, the handle 40 can be turned through an angle relative to the drawable carrier 30 from the horizontal position to a vertical locking position to force the locating members 44 into engagement with the upright ends of the retaining portions 54, thereby locking the drawable carrier 30, which carries the hard disk drive 20, to the fixed casing 50.

The two spring strips 60 are elongated, elastically deformable and electrically conductive conducting strips, each having a smoothly arched middle part and a plurality of mounting through holes 62 for coupling to the mounting pins 32 of the drawable carrier 30 to secure the spring strips 60 to the drawable carrier 30. When the drawable carrier 30 carrying the hard disk drive 20 is inserted into the fixed casing 50, the spring strips 60 are closely stopped between the fixed casing 50 that is grounded with the computer housing (not shown) and the hard disk drive 20, such that the hard disk drive 20 is grounded.

When the user wants to fasten the hard disk drive 20 to the drawable carrier 30, the user can pull the two opposite lateral sidewalls of the drawable carrier 30 outwards in reversed direction and then cap the drawable carrier 30 on the hard disk drive 20 to force the respective pins 32 of the drawable carrier 30 into the respective mounting holes 22 of the hard disk drive 20, and then release the hand from the drawable carrier 30 for allowing the drawable carrier 30 to return to its former shape. Thus, the hard disk drive 20 can be easily fastened to the drawable carrier 30, as shown in FIG. 4.

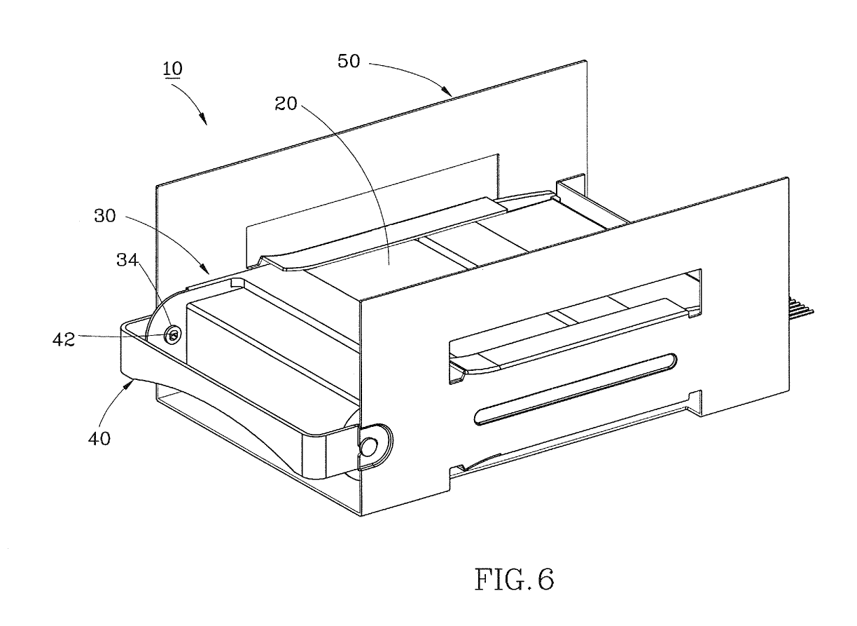

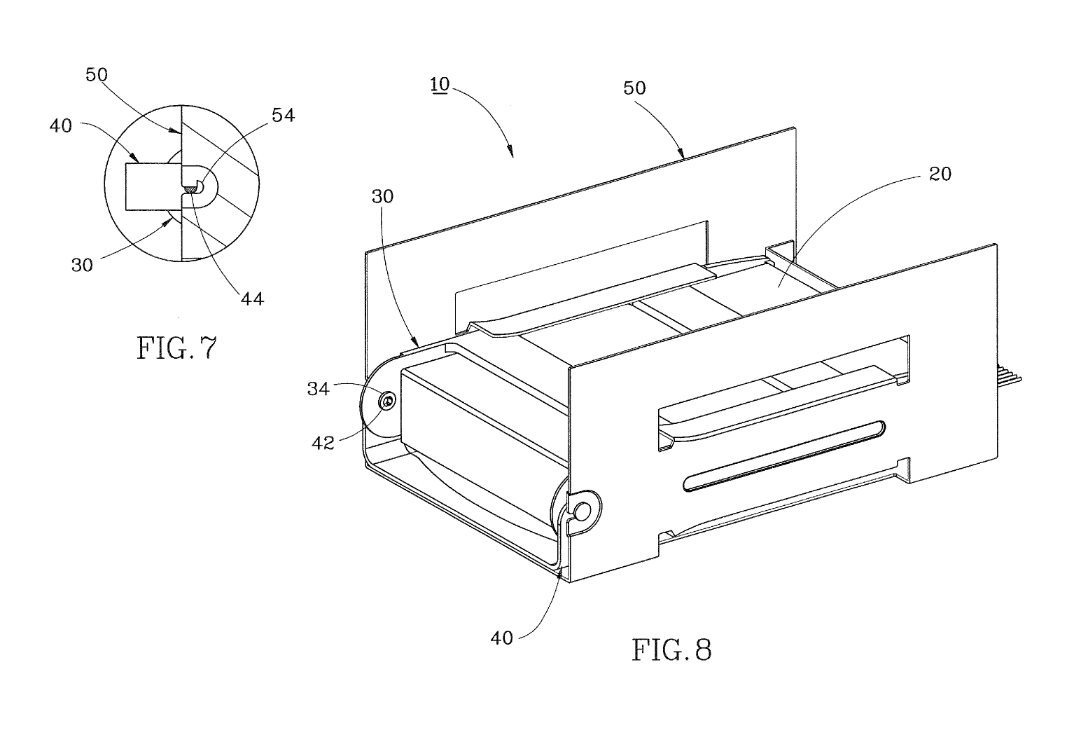

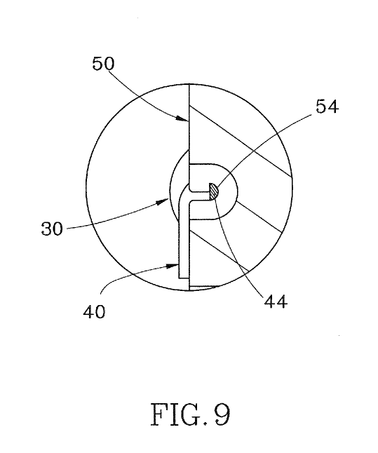

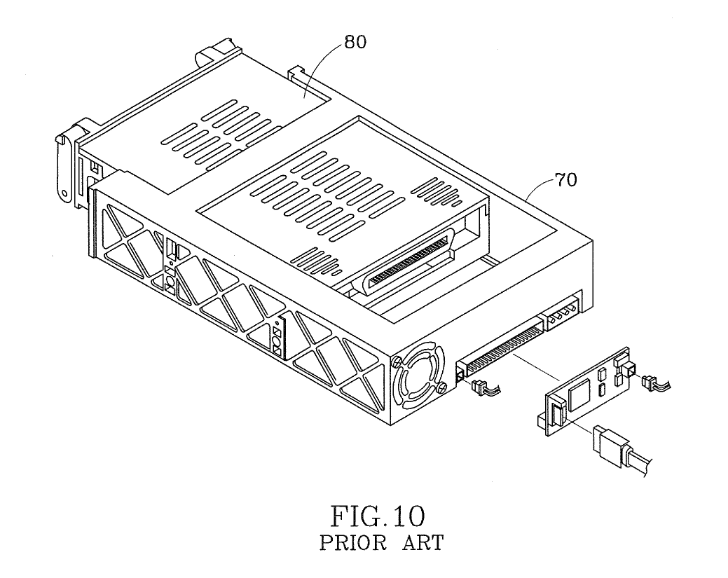

By means of inserting the drawable carrier 30 carrying the hard disk drive 20 into the receiving space of the fixed casing 50 and then applying a forward pressure to the handle 40 to push the drawable carrier 30 along the bearing portions 52, the drawable carrier 30 can be installed in the fixed casing 50. When about one half of the drawable carrier 30 is pushed into the receiving space of the fixed casing 50, the spring strips 60 are squeezed by inner surfaces of the lateral sidewalls of the fixed casing 50 to deform and held closely attached to the fixed casing 50 and the hard disk drive 20, and therefore hard disk drive 20 held by the drawable carrier 30 is grounded by means of the grounded fixed casing 50. When continuously pushing the drawable carrier 30 toward the receiving space of the fixed casing 50, the locating members 44 of the handle 40 will be respectively forced into the horizontal sections of the retaining portions 54, i.e. the slots, as shown in FIGS. 6 and 7. After the drawable carrier 30 has been completely inserted into the receiving space of the fixed casing 50, the user can turn the handle 40 relative to the drawable carrier 30 to a vertical locking position to force the locating members 44 into positive engagement with the upright ends of the retaining portions (slots) 54, thereby locking the drawable carrier 30 to the fixed casing 50, as shown in FIGS. 8 and 9. At this moment, the locating members 44 engaged with the end portions of the retaining portion (slots) 54 will stop the drawable carrier 30 and the hard disk drive 20 from withdrawal out of the fixed casing 50. If the user wants to remove the hard disk drive 20, the user only has to reverse the aforesaid operation procedure.

As stated above, the present invention utilizes not only the elastically deformable characteristic of the drawable carrier 30 for easy installation of the hard disk drive 20 in the drawable carrier 30 but also the engageable locating members 44 and retaining portions 54 to lock the drawable carrier 30 to the fixed casing 50 without using any tools or fastener such as screws. Therefore, the installation procedure of the hard disk drive drawer of the present invention is simple and convenient. Further, by means of the connection of the spring strips 60 between the hard disk drive 20 and the grounded fixed casing 50, the hard disk drive 20 can be well grounded to prevent itself from damage due to ESD phenomenon.

In conclusion, the hard disk drive drawer provided by the present invention utilizes the elastically deformable characteristic of the drawable carrier for easy and quick installation of the hard disk drive and the connection arrangement of two spring strips to preventing the hard disk drive held by the drawable carrier from ESD damage.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A hard disk drive drawer mountable inside a computer housing for holding a hard disk drive therein, the hard disk drive drawer comprising:
a fixed casing mountable inside the computer housing, the fixed casing having a retaining portion;
a drawable carrier elastically deformable for holding a hard disk drive therein, the drawable carrier being detachably received in the fixed casing; and
a handle pivotally connected with the drawable carrier and provided with a locating member, which is engageable with the retaining portion of the fixed casing when the drawable carrier is received in the fixed casing and the handle is turned relative to the drawable carrier to a locking position.

2. The hard disk drive drawer as claimed in claim 1, wherein the fixed casing comprises two opposite lateral sidewalls, on each of which a bearing portion is provided for supporting the drawable carrier inside the fixed casing.

3. The hard disk drive drawer as claimed in claim 2, wherein the bearing portions of the fixed casing are plates extending respectively and horizontally from the opposite lateral sidewalls of the fixed casing.

4. The hard disk drive drawer as claimed in claim 1, wherein the handle is substantially a U-shaped member having two arms pivotally connected with two opposite lateral sidewalls of the drawable carrier.

5. The hard disk drive drawer as claimed in claim 4, wherein the two arms of the handle each have a pivot pivotally inserted into a pivot hole provided at each of the two opposite lateral sidewalls of the drawable carrier.

6. The hard disk drive drawer as claimed in claim 1, wherein the retaining portion of the fixed casing is a slot, and the locating member of the handle is a rod member insertable into and positionable in the slot.

7. The hard disk drive drawer as claimed in claim 6, wherein the slot of the fixed casing has a horizontal section and an upright end, and the rod member of the handle has a substantially semicircle-shaped cross-section, which is slidably insertable into the horizontal section of the slot when the handle is kept horizontal relative to the drawable carrier and engageable with the upright end of the slot when the handle is turned relative to the drawable carrier to the locking position in a vertical manner.

8. The hard disk drive drawer as claimed in claim 1, further comprising at least one spring strip mounted in the drawable carrier and stopped against the fixed casing.

9. The hard disk drive drawer as claimed in claim 8, wherein the at least one spring strip and the fixed casing are respectively made of an electrically conductive material.

10. The hard disk drive drawer as claimed in claim 8, wherein the drawable carrier comprises a plurality of pins; the spring strip has a plurality of through holes for insertion of the pins of the drawable carrier.

11. The hard disk drive drawer as claimed in claim 8, wherein the spring strip has a smoothly arched middle part.
